(19) United States
(12) Patent Application Publication
(10) Pub. No.: US 2025/0393244 A1
(43) Pub. Date: Dec. 25, 2025

(54) FORMING CONTACT IN TIGHT TIP-TO-TIP SPACE

(71) Applicant: International Business Machines Corporation, Armonk, NY (US)

(72) Inventors: Tsung-Sheng Kang, Ballston Lake, NY (US); Alexander Reznicek, Troy, NY (US); Sagarika Mukesh, ALBANY, NY (US); Ruilong Xie, Niskayuna, NY (US)

(21) Appl. No.: 18/747,659

(22) Filed: Jun. 19, 2024

(51) Int. Cl. H01L 29/417; H01L 29/06; H01L 29/40; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/01

(57) ABSTRACT

Embodiments of the invention disclose semiconductor structures. According to an embodiment, the semiconductor structure may include a first source/drain region of a first transistor and a second source/drain region of a second transistor. The semiconductor structure may additionally include a source/drain contact block having a first source/drain contact in contact with the first source/drain region of the first transistor and a second source/drain contact in contact with the second source/drain region of the second transistor. According to the embodiment, the first source/drain contact and the second source/drain contact of the source/drain contact block are separated by a lower contact cut and an upper contact cut.

### BACKGROUND

The present invention generally relates to semiconductor structures, and more particularly to forming contact in tight tip-to-tip space.

Semiconductor devices are widely used. These semiconductor devices are comprised of semiconductor chips that are manufactured to include various active and passive devices. Active devices include transistors, and they are powered through contacts to their source/drain regions and gates. With the increase in device density in the economy of scale, distances and/or spacing between source/drain regions and/or gate decrease dramatically which, in turn, creates difficulty of forming contacts without the risk of short across a tight tip-to-tip. Moreover, the increasing device density further risks inadequate contact between the contact and the source drain regions as well as misalignment of M1 and VA.

### SUMMARY

According to an embodiment of the present invention, a semiconductor structure is provided. The semiconductor structure may include a first source/drain region of a first transistor and a second source/drain region of a second transistor. According to the embodiment, the semiconductor structure may additionally include a source/drain contact block having a first source/drain contact in contact with the first source/drain region of the first transistor and a second source/drain contact in contact with the second source/drain region of the second transistor. According to the embodiment, the first source/drain contact and the second source/drain contact of the source/drain contact block are separated by a lower contact cut and an upper contact cut.

According to another embodiment of the present invention, a semiconductor structure is provided. The semiconductor structure may include two or more source/drain regions and two cuts that are parallel, horizontally offset, vertically staggered, and filled with dielectric material formed horizontally between the two or more source/drain regions.

According to another embodiment of the present invention, a semiconductor structure is provided. The semiconductor structure may include a source/drain contact and two or more cuts vertically bifurcating the source/drain contact.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2 and 3 are cross-sectional views of a semiconductor structure 10 and a semiconductor structure 20, according to a current state of the art;

FIGS. 4 and 5 are cross-sectional views of a semiconductor structure 100 after self-aligned contact (SAC) cap formation and chemical mechanical planarization (CMP), according to an embodiment of the invention;

FIGS. 6 and 7 are cross-sectional views of the semiconductor structure 100 following the formation of a merged contact within the ILD, according to an embodiment of the invention;

FIGS. 8 and 9 are cross-sectional views of the semiconductor structure 100 after cut patterning of the lower contact and a CMP, according to an embodiment of the invention;

FIGS. 10 and 11 are cross-sectional views of the semiconductor structure 100 after filling of the cut patterning with a dielectric fill and recessing the contact, according to an embodiment of the invention;

FIGS. 12 and 13 are cross-sectional views of the semiconductor structure 100 after an etching process is used on the lower contact cut 146, according to an embodiment of the invention;

FIGS. 14 and 15 are cross-sectional views of the semiconductor structure 100 after the optional process of further recessing the lower contact, according to an embodiment of the invention;

FIGS. 16 and 17 are cross-sectional views of the semiconductor structure 100 after filling the void with a sacrificial material fill, according to an embodiment of the invention;

FIGS. 18 and 19 are cross-sectional views of the semiconductor structure 100 after forming an upper contact cut patterning, according to an embodiment of the invention;

FIGS. 20 and 21 are cross-sectional views of the semiconductor structure 100 after a dielectric fill and recess, according to an embodiment of the invention;

FIGS. 22 and 23 are cross-sectional views of the semiconductor structure 100 after removing the sacrificial fill material, according to an embodiment of the invention;

FIGS. 24 and 25 are cross-sectional views of the semiconductor structure 100 after upper contact metallization, according to an embodiment of the invention;

FIGS. 26 and 27 are cross-sectional views of another embodiment of the semiconductor structure 100 after upper contact metallization, according to an embodiment of the invention;

FIGS. 28 and 29 are cross-sectional views of the semiconductor structure 100 after formation of a back-end-of-line (BEOL), ILD, V0, and M1, according to an embodiment of the invention;

FIGS. 30 and 31 are cross-sectional views of a semiconductor structure 200 after recessing the lower contact, according to an embodiment of the invention;

FIGS. 32 and 33 are cross-sectional views of the semiconductor structure 200 after a sacrificial material fill and cut patterning, according to an embodiment of the invention; and

FIGS. 34 and 35 are cross-sectional views of the semiconductor structure 200 after formation of a back-end-of-line (BEOL), ILD, V0, and M1, according to an embodiment of the invention;

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sublithographic” may refer to a dimension or size less than current dimensions achievable by photolithographic processes, and the term “lithographic” may refer to a dimension or size equal to or greater than current dimensions achievable by photolithographic processes. The sublithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

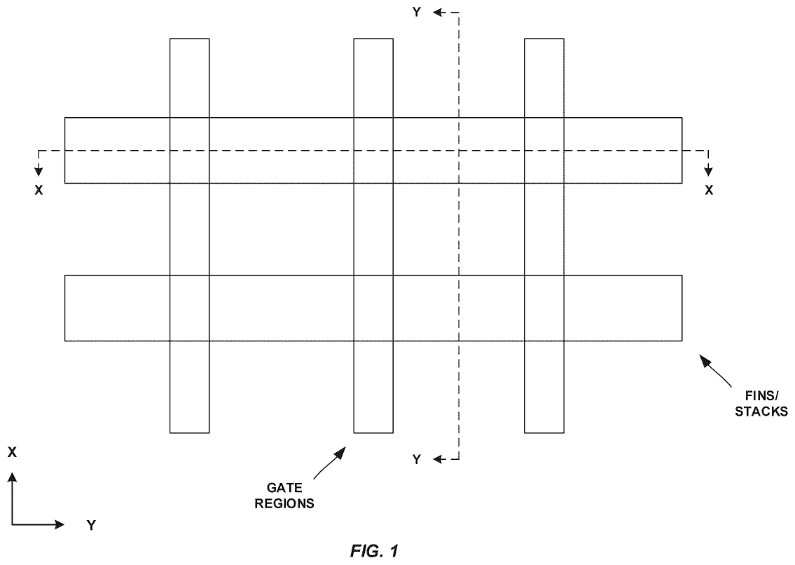

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-35 represent cross section views oriented as indicated in FIG. 1.

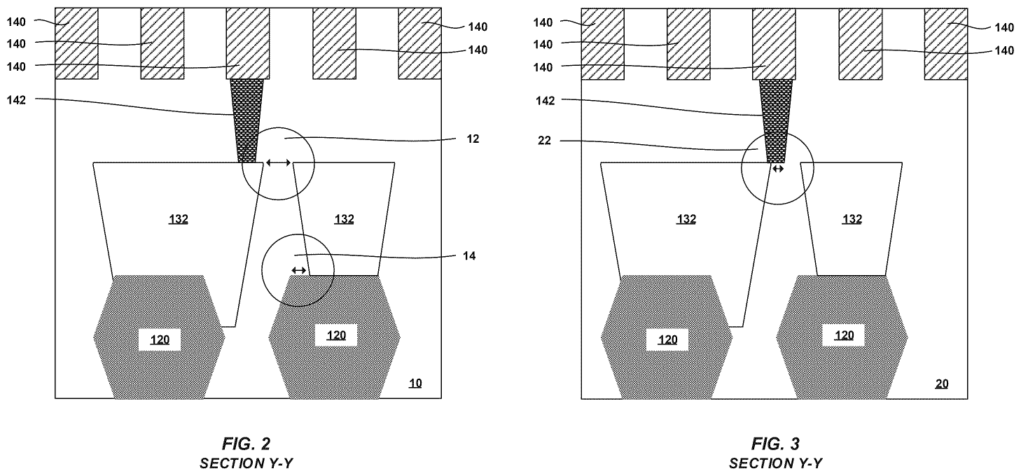

Referring now to FIGS. 2 and 3, semiconductor structure 10 and semiconductor structure 20 are depicted solely for purposes of illustrating problems with the state of the art in semiconductor fabrication. Semiconductor structures 10 and 20 each comprise source/drain region 120, lower contact 132, VA 142, and M1 140. As used in FIGS. 2 and 3, circles and arrows are non-structural and are merely used illustratively to emphasize the described problem areas. FIGS. 2 and 3 show a cross-sectional view of the semiconductor structures 10 and 20, respectively, taken along line YY shown in FIG. 1.

First, FIG. 2 depicts problems by reference characters 12 and 14. 12 illustrates the problem of a tight contact tip-to-tip. Here, as illustrated by the circled arrow referenced by 12, two of contact 132 are close enough for possibly causing unintended conductivity.

In addition, 14 depicts an inadequate epitaxial contact area between the lower contact 132 and the source and drain regions 120 due to process limitation. As a result, the lower contact 132 fails to adequately contact the source/drain region 120 and may result in a poor or no conductivity. In addition, highly reduced contact area results in high contact resistance, degrading device performance.

Lastly, and as depicted by 22 within the semiconductor structure 20, the third problem is a partial or total misalignment of the M1 140 and the VA 142 with the lower contact 132. This misalignment results in a poor contact and conductivity between the VA 142 and the contact 132. Here, again, the reduced contact area additionally results in high contact resistance, degrading device performance. As illustrated, the lower contact 132 needs to extend horizontally to ensure contact with the VA 142, however doing so makes a space between the lower contact 132 and the adjacent lower contact 132 (tip-to-tip) too tight and risk shorting if there are any manufacturing imperfections. On the other hand, increasing space between the lower contact 132 and the adjacent lower contact 132 will result in a small contact area between the lower contact 132 and VA 142.

The claimed invention is intended to address the shortcomings detailed above through the use of selectively placed dielectric-filled cuts within an upper and lower contact, and is now described in greater detail.

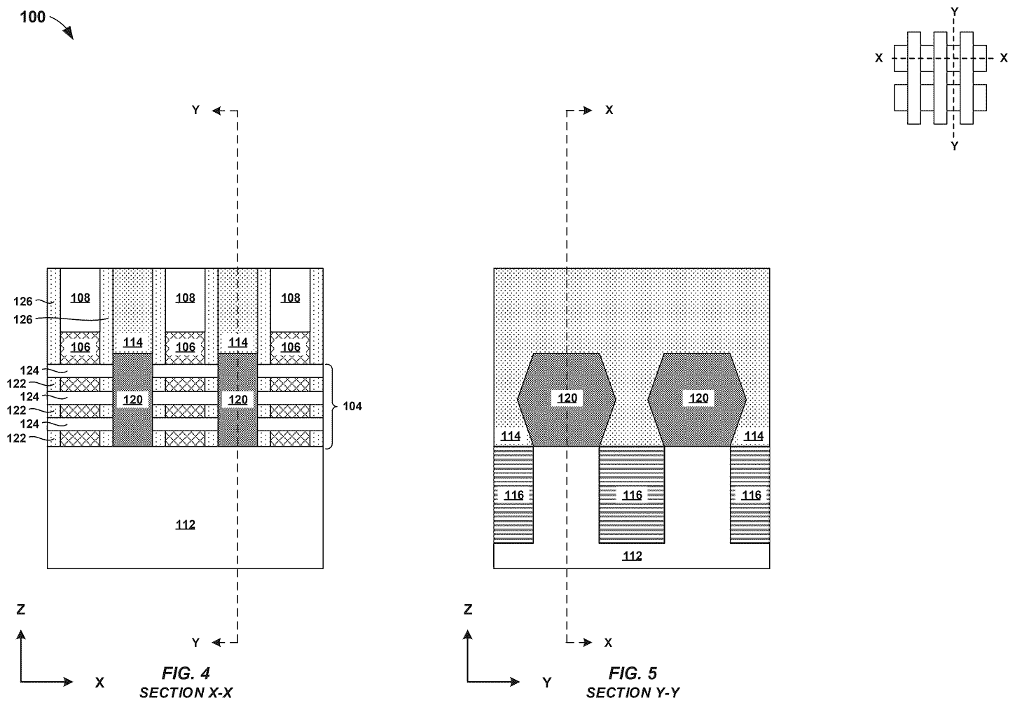

Referring now to FIGS. 4 and 5, a structure 100 is shown during an intermediate step of a method of fabricating a semiconductor structure after self-aligned contact (SAC) cap formation and chemical mechanical planarization (CMP), according to an embodiment of the invention. FIG. 4 depicts a cross-sectional view of the structure 100 shown in FIG. 5 taken along line XX and FIG. 5 depicts a cross-sectional view of the structure 100 shown in FIG. 4 taken along line YY.

The structure 100 illustrated in FIGS. 4-5 includes an array of nanosheet transistors formed on a substrate 112 in accordance with known techniques.

As illustrated, the array of nanosheet transistors includes nanosheet stacks 104. Each nanosheet stack 104 includes a plurality of silicon channels 124 surrounded by a single gate 106. For example, the cross-section in FIG. 4 illustrates a transistor comprising a first and second of the source/drain region 120 on either side of the middle gate 106.

In the present embodiment, the substrate 112 may be any bulk substrate made from any known semiconductor materials such as, for example, silicon, germanium, silicon-germanium alloy, and compound (e.g. III-V and II-VI) semiconductor materials. For example, the substrate 112 may be made from silicon.

The structure 100 further includes source/drain region 120 generally arranged between adjacent nanosheet stacks 104, as illustrated.

The source/drain region 120 are formed on top of the substrate 112 according to known techniques. Specifically, the source/drain region 120 are disposed between adjacent nanosheet stacks 104 in direct contact with exposed ends of the silicon channels 124. The source/drain region 120 may be epitaxially grown from the exposed ends of the silicon channels 124 according to known techniques.

The structure 100 further includes shallow trench isolation (STI) regions 116 which extend partially into the substrate 112 below the array of nanosheet transistors. The STI regions 116 may each include an isolation fill. For example, the isolation fill is silicon oxide (SiOx) or silicon nitride (SiN).

The structure 100 further includes inner spacers 122, gate spacers 126, a self-aligned contact (SAC) cap 108, and an interlayer dielectric (ILD) 114.

The inner spacers 122 are disposed between alternate channels (124), and laterally separate the gates 106 from the source/drain region 120, as illustrated. The inner spacers 122 provide necessary electrical insulation between the gates 106 and the source/drain region 120.

The gate spacers 126 are added to define the channel length and the source/drain region 120, and ultimately electrically insulate the gates 106 from subsequently formed structures, such as, for example, source drain contact structures. The gate spacers 126 are critical for electrically insulating the gates 106 from the source/drain region 120 or subsequently formed contact structures.

In embodiments, the SAC cap 108 provides a protective dielectric layer over the gate 106.

The structure further includes the ILD 114 formed on top of the STI regions 116 in contact with and partially surrounding the source/drain region 120.

The inner spacers 122, the gate spacers 126, the SAC cap 108, and the ILD 114 are composed of any suitable interlayer dielectric material (though not necessarily the same material), such as, for example, oxides such as silicon oxide (SiOₓ), nitrides such as silicon nitride (SiₓN_{y}), and/or low-K materials such as SiCOH or SiBCN. In another embodiment, they are composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, they are self-planarizing material such as a spin-on glass (SOG) or a spin-on low-k dielectric material such as SiLK™. As noted above, the inner spacers 122, the gate spacers 126, the SAC cap 108, and the ILD 114 may be composed of any of the above materials but all are not necessarily the same material(s).

Although only a limited number of components, devices, or structures are shown and described, embodiments of the present invention shall not be limited by any quantity otherwise illustrated or discussed herein.

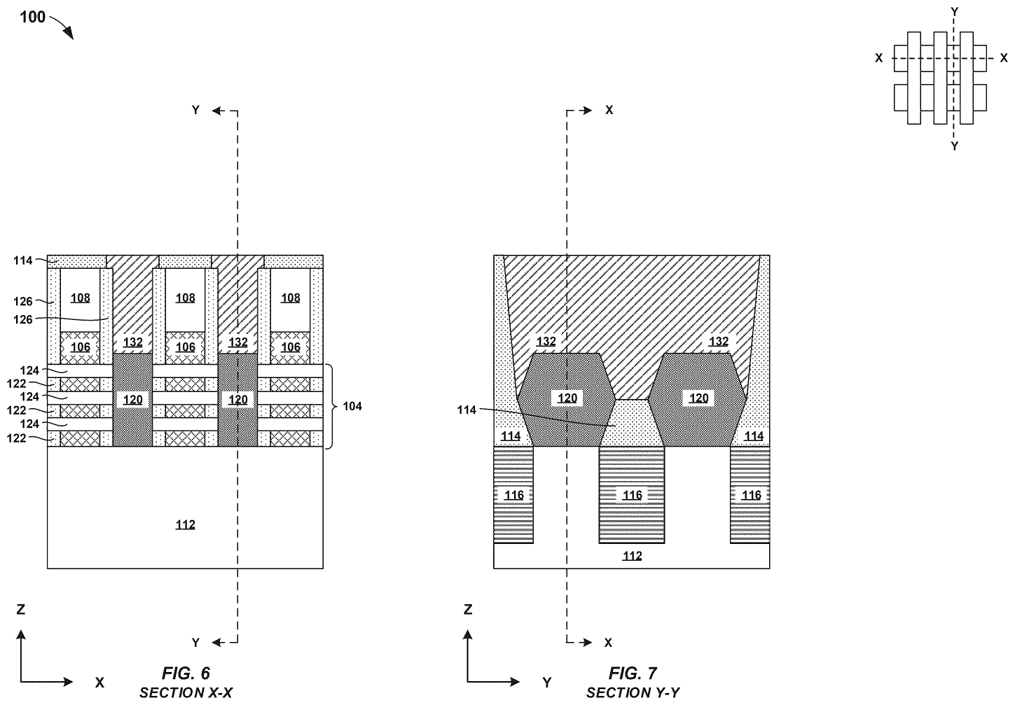

Referring now to FIGS. 6 and 7, the structure 100 is shown during an intermediate step of a method of fabricating a semiconductor structure following the formation of a merged contact with the ILD, according to an embodiment of the invention. FIG. 6 depicts a cross-sectional view of the structure 100 shown in FIG. 7 taken along line XX and FIG. 7 depicts a cross-sectional view of the structure 100 shown in FIG. 6 taken along line YY.

In embodiments, the lower contact 132 is formed within the ILD 114. As illustrated, the ILD 114 may be etched down to and exposing a top and upper sides of the source/drain region 120. As further illustrated, the ILD 114 is not removed from areas that include along bottom sides of the source/drain region 120, areas extending upward and outward from the outermost tips of the source/drain region 120, and on a top portion of the SAC cap 108. The ILD 114 may be removed using known techniques.

A lower contact 132 may be formed in the void formed by removal of the ILD 114. The lower contact 132 may be composed of a conducting material and may be deposited by known techniques, for example, fill and polish, physical vapor deposition (PVD), sputtering, metalorganic chemical vapor deposition (MOCVD), etc. The lower contact 132 may have a liner (not shown). The liner may be a dielectric liner formed conformally along a top surface of the lower contact 132 according to known techniques. In some embodiments, for example, the liner may be composed of low-k materials, such as, for example, SiN, SiBCN, SiOCN, SiOC-, or other combinations thereof. According to embodiments of the present invention, the liner provides added etch selectivity during backside processing.

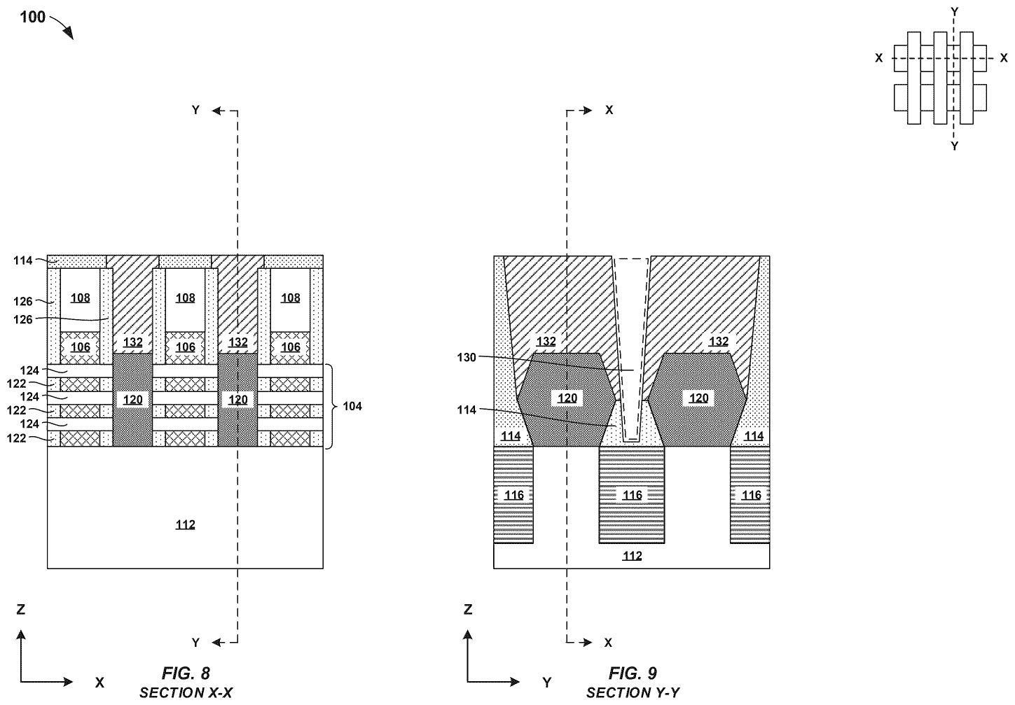

Referring now to FIGS. 8 and 9, the structure 100 is shown after cut patterning of the lower contact and a CMP process, according to an embodiment of the invention. FIG. 8 depicts a cross-sectional view of the structure 100 shown in FIG. 9 taken along line XX and FIG. 9 depicts a cross-sectional view of the structure 100 shown in FIG. 8 taken along line YY.

Next, a cut patterning is performed to create a lower contact cut opening 130 in the lower contact 132 using known techniques. As illustrated, the lower contact cut opening 130 is made to intersect the lower contact 132 and at least a portion of the ILD 114 between the source/drain region 120. For example, the lower contact cut opening 130 may be made to extend in between tip-to-tip portions of two of the source/drain region 120.

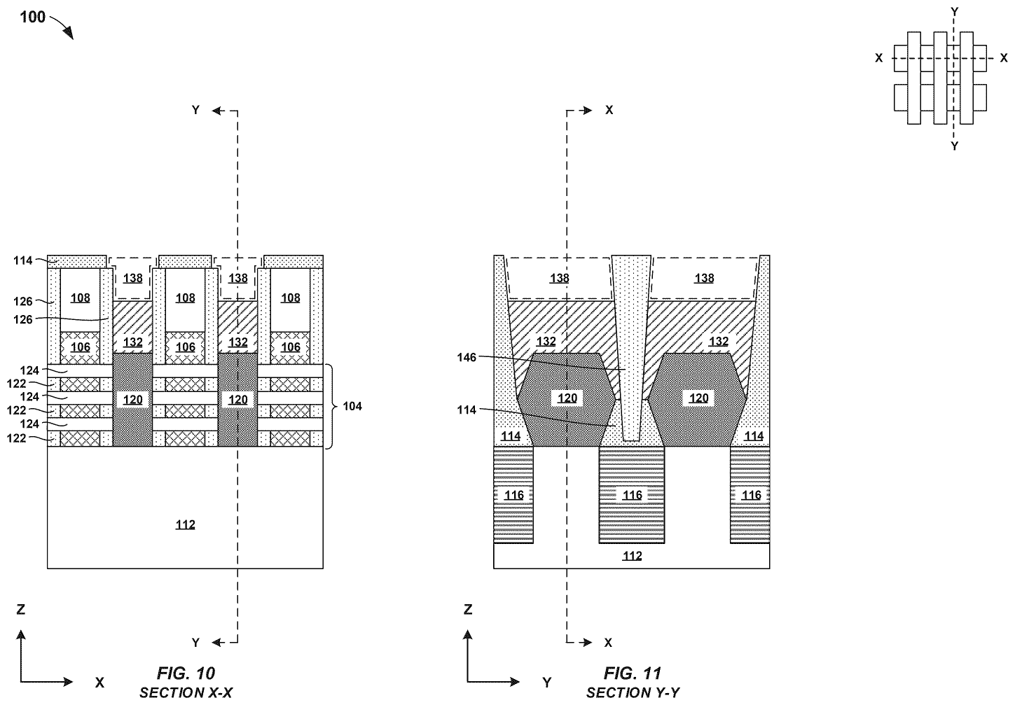

Referring now to FIGS. 10 and 11, the structure 100 is shown after filling of the cut patterning with a dielectric fill and recessing the contact, according to an embodiment of the invention. FIG. 10 depicts a cross-sectional view of the structure 100 shown in FIG. 11 taken along line XX and FIG. 11 depicts a cross-sectional view of the structure 100 shown in FIG. 10 taken along line YY.

Then, the lower contact cut opening 130 is filled with a dielectric, forming a lower contact cut 146. The dielectric filling of the lower contact cut 146 may be a same or difference dielectric than gate spacer 126 or SAC cap 108, such as SiC, AlNx, AlOx, etc. Lastly, a CMP process is performed to make a top surface of the lower contact 132 and a top surface of the lower contact cut 146 coplanar. In embodiments, the lower contact cut 146 insulates/isolates between the two source/drain region 120, the two lower contact 132, and/or two upper contacts 160.

In embodiments, the lower contact 132 may be recessed using known techniques to create a void 138. For example, the lower contact 132 may be etched to roughly half its height. As illustrated, the lower contact cut 146 is selectively unetched.

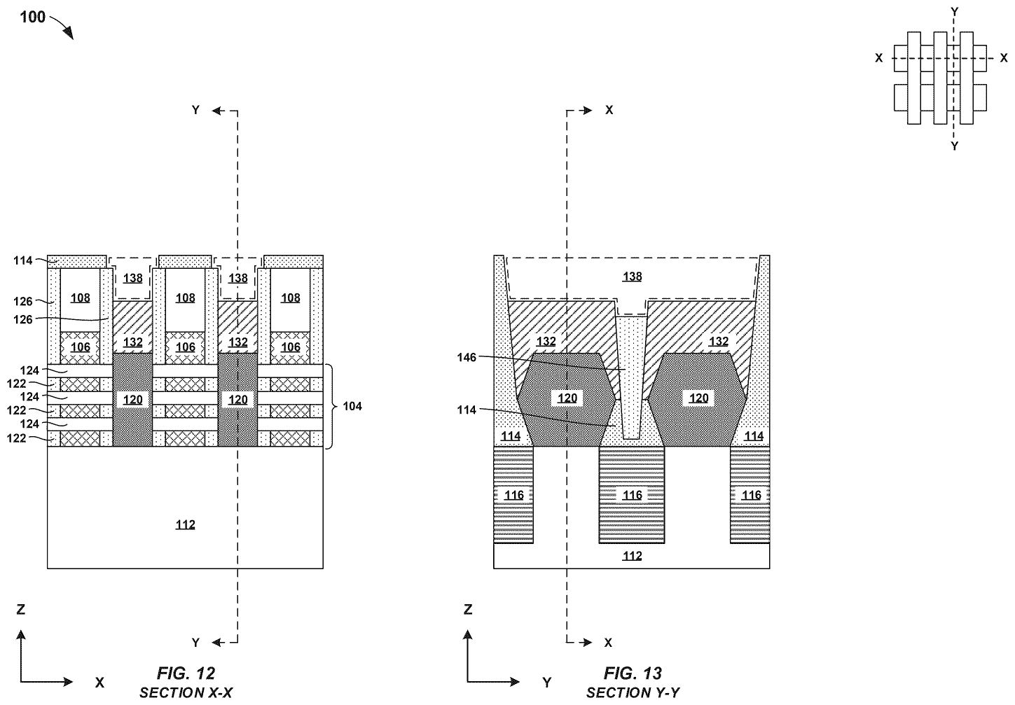

Referring now to FIGS. 12 and 13, the structure 100 is shown after an etching process is used on the lower contact cut 146, according to an embodiment of the invention. FIG. 12 depicts a cross-sectional view of the structure 100 shown in FIG. 13 taken along line XX and FIG. 13 depicts a cross-sectional view of the structure 100 shown in FIG. 12 taken along line YY.

In embodiments, an etching process is applied to the lower contact cut 146 using known techniques. The lower contact cut 146 may be etched to a height that is different than that of the lower contact 132. As illustrated, a top surface of the lower contact cut 146 may have a height that is less than that of the lower contact 132. The etching may expand the void 138 roughly proportionally to the etched amount.

It should be noted that the independent etching (or individually selectively etching) of the lower contact 132 and the lower contact cut 146 described above may be performed in any order. In another embodiment, the lower contact 132 and the lower contact cut 146 may be etched together in a same process.

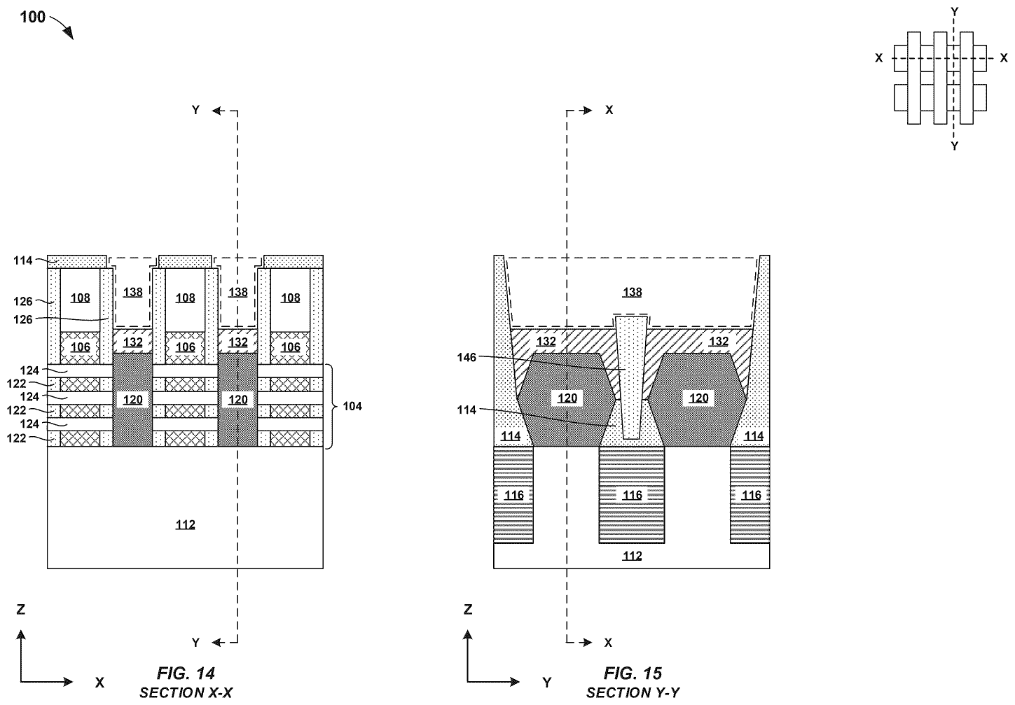

Referring now to FIGS. 14 and 15, the structure 100 is shown after the optional process of further recessing the lower contact, according to an embodiment of the invention. FIG. 14 depicts a cross-sectional view of the structure 100 shown in FIG. 15 taken along line XX and FIG. 15 depicts a cross-sectional view of the structure 100 shown in FIG. 14 taken along line YY.

Optionally, the lower contact 132 may be further recessed and the void 138 further expanded. Restated, the lower contact 132 and the lower contact cut 146 do not necessarily need to have a coplanar top surface. As illustrated, the lower contact cut 146 is above the lower contact 132.

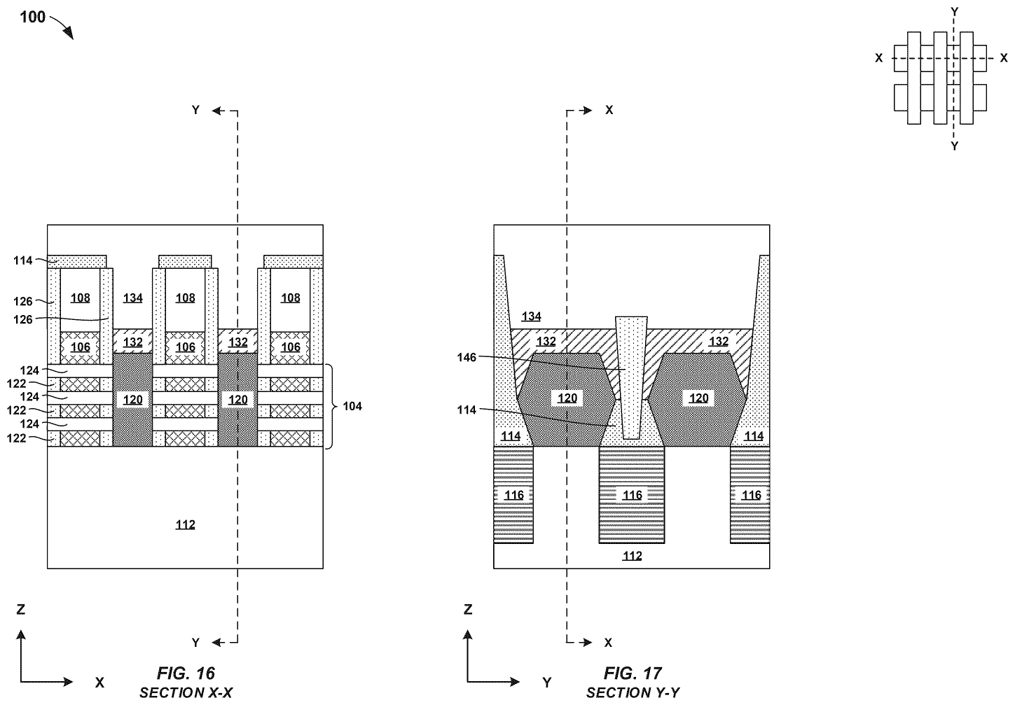

Referring now to FIGS. 16 and 17, the structure 100 is shown after filling the void with a sacrificial material, according to an embodiment of the invention. FIG. 16 depicts a cross-sectional view of the structure 100 shown in FIG. 17 taken along line XX and FIG. 17 depicts a cross-sectional view of the structure 100 shown in FIG. 16 taken along line YY.

Next, a sacrificial material 134 is deposited on top of portions of the of the lower contact 132, the lower contact cut 146, and the ILD 114. For example, the sacrificial material 134 may be, for example, OPL or SOG. As illustrated, the sacrificial material 134 may be deposited using known techniques and in an amount sufficient to cap the lower contact 132, the lower contact cut 146, and the ILD 114.

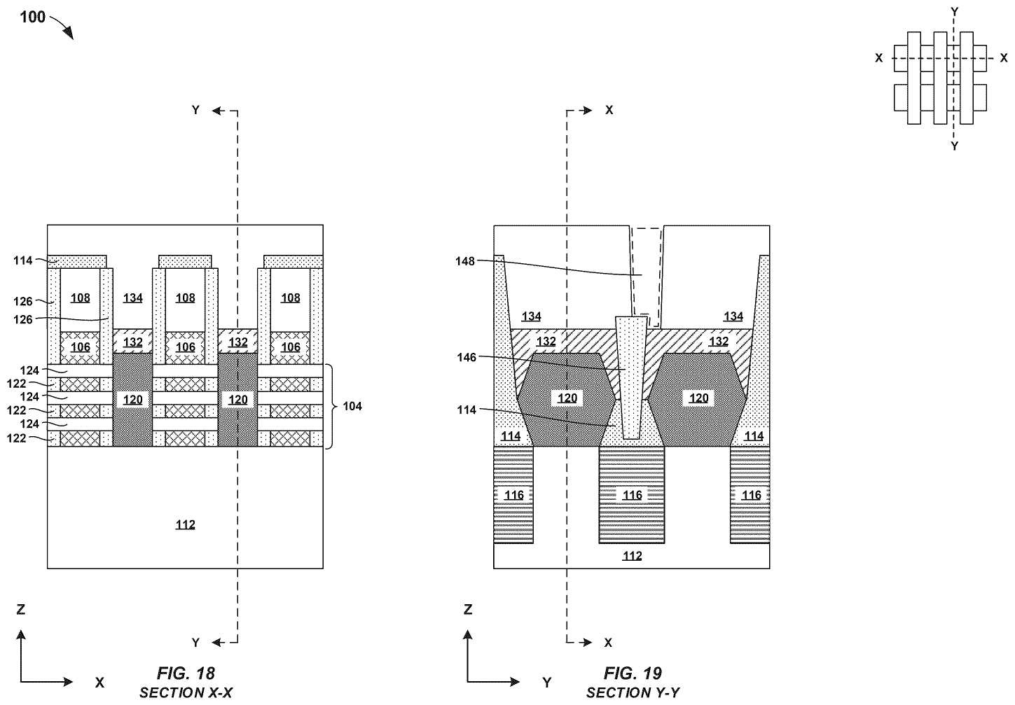

Referring now to FIGS. 18 and 19, the structure 100 is shown after forming an upper contact cut patterning, according to an embodiment of the invention. FIG. 18 depicts a cross-sectional view of the structure 100 shown in FIG. 19 taken along line XX and FIG. 19 depicts a cross-sectional view of the structure 100 shown in FIG. 18 taken along line YY.

Next, a cut patterning is performed to create an upper contact cut opening 148 in the sacrificial material 134 using known techniques. As illustrated, the upper contact cut opening 148 is made to a depth that exposes a top surface of the lower contact cut 146. Further, the upper contact cut opening 148 may be formed on top of but be misaligned vertically from the lower contact cut 146.

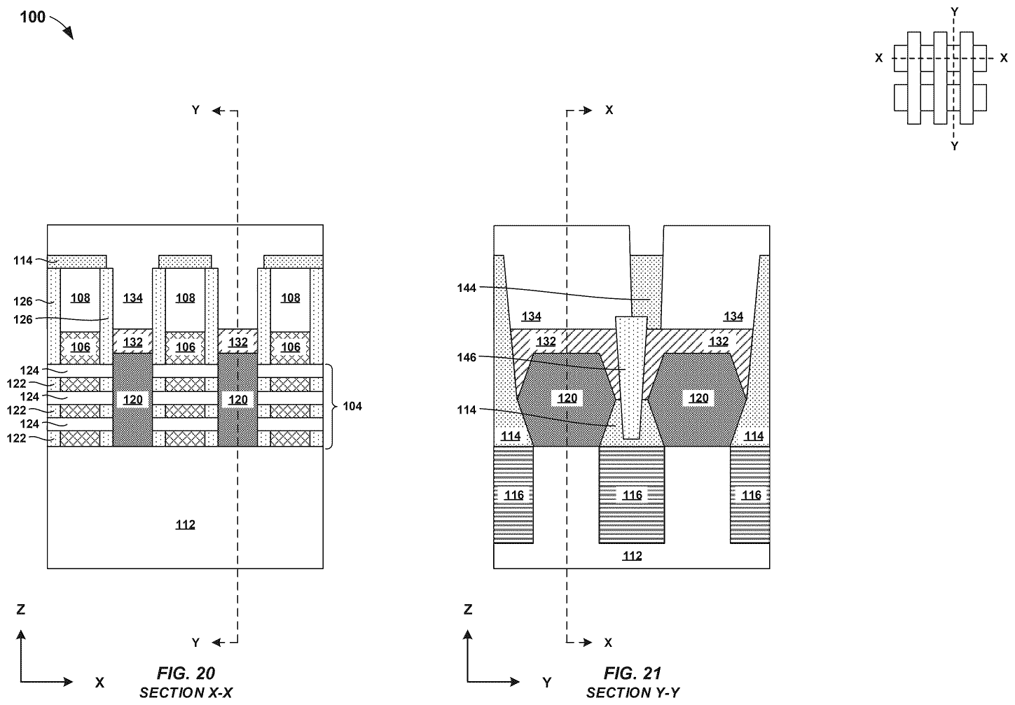

Referring now to FIGS. 20 and 21, the structure 100 is shown after a dielectric fill and recess, according to an embodiment of the invention. FIG. 20 depicts a cross-sectional view of the structure 100 shown in FIG. 21 taken along line XX and FIG. 21 depicts a cross-sectional view of the structure 100 shown in FIG. 20 taken along line YY.

First, a dielectric fill is used to fill the upper contact cut opening 148 and form an upper contact cut 144. In some embodiments, and unlike the fill used in the lower contact cut 146, the upper contact cut 144 can be filled with a same dielectric as that of the gate spacer 126 or the SAC cap 108, such as SiN, SiOCN, SiBCN, SiOC, etc. Then, the upper contact cut 144 is recessed. In embodiments, the upper contact cut 144 insulates/isolates between the two lower contacts 132 and/or the two upper contacts 160.

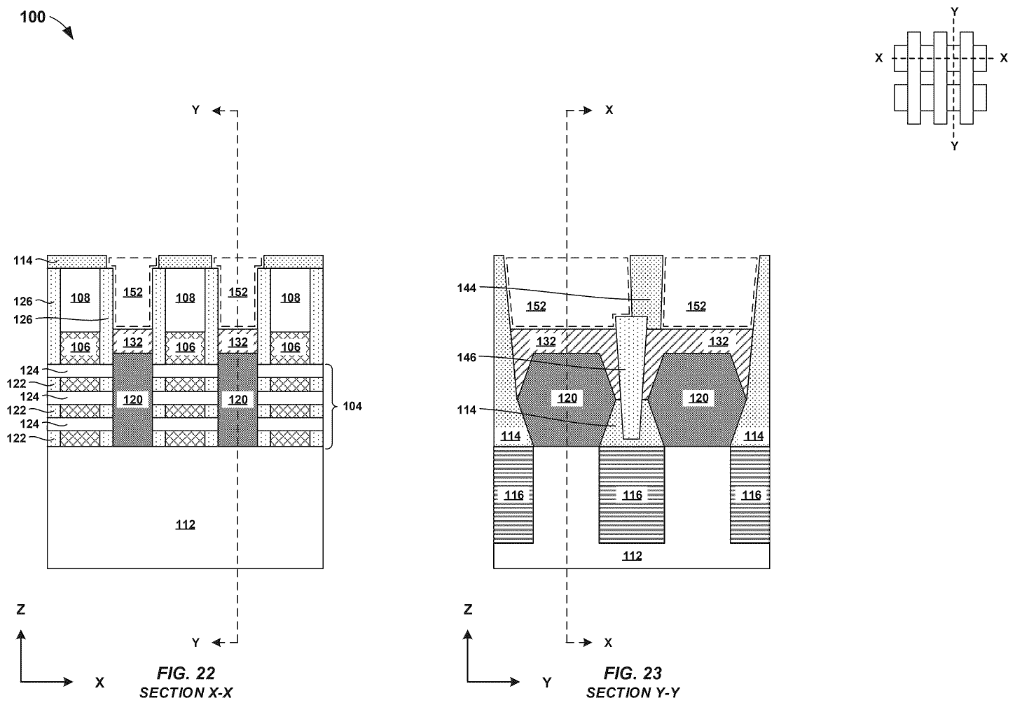

Referring now to FIGS. 22 and 23, the structure 100 is shown after removing the sacrificial material, according to an embodiment of the invention. FIG. 22 depicts a cross-sectional view of the structure 100 shown in FIG. 23 taken along line XX and FIG. 23 depicts a cross-sectional view of the structure 100 shown in FIG. 22 taken along line YY.

Next, the sacrificial material 134 is removed using known techniques, creating a void 152. As illustrated, the sacrificial material 134 may be removed to expose the ILD 114, the lower contact 132, a top portion of the lower contact cut 146, and the upper contact cut 144.

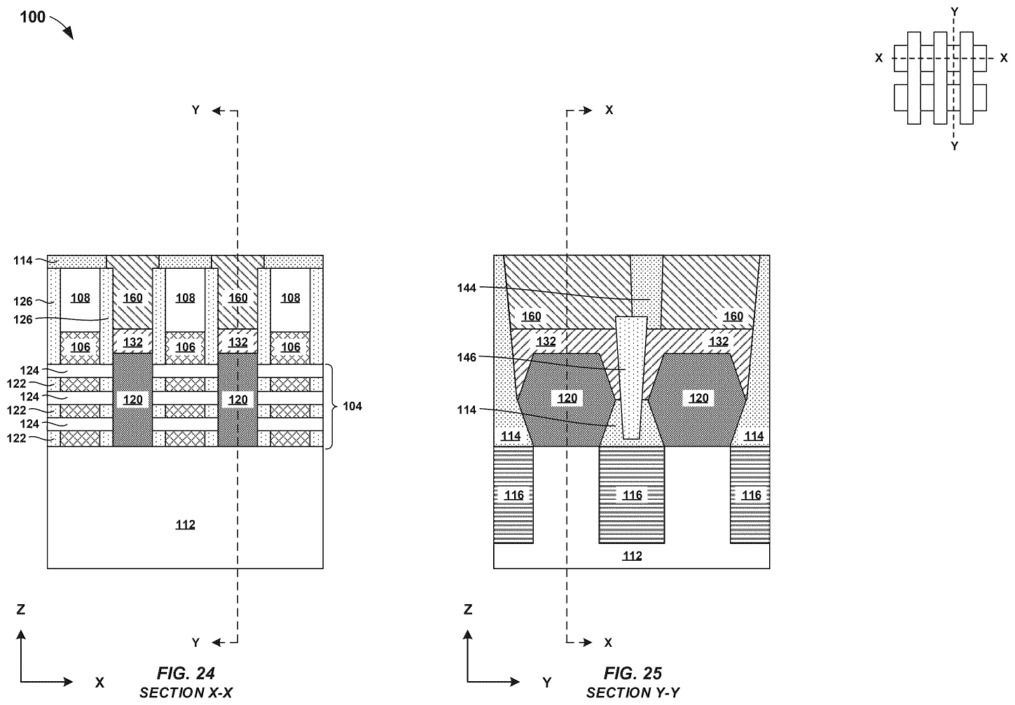

Referring now to FIGS. 24 and 25, the structure 100 is shown after upper contact metallization, according to an embodiment of the invention. FIG. 24 depicts a cross-sectional view of the structure 100 shown in FIG. 25 taken along line XX and FIG. 25 depicts a cross-sectional view of the structure 100 shown in FIG. 24 taken along line YY.

Next, an upper contact 160 is formed within the void 152 using known techniques. The upper contact 160 may be formed of metal. The metal may be a same or a different metal as that comprising the lower contact 132. As illustrated, FIGS. 24-25 show an embodiment in which the lower contact cut 146 is planarly proud relative to the lower contact 132, where it then meets the upper contact cut 144. As further illustrated, the lower contact cut 146 and the upper contact cut 144 collectively intersect and provide electrical insulation between portions of the lower contact 132, the upper contact 160, and the source/drain region 120. Similar to the lower contact 132, the upper contact 160 may have a liner.

The upper contact 160 may be clearly differentiated from the lower contact 132 because either: the lower contact 132 has liner and upper contact 160 is linerless metal fill, or both the lower contact 132 and the upper contact 160 have liners, and therefore a liner exist at their interface. In embodiments, the dielectric thickness between closest contacts (e.g., the liner between the lower contact 132 and the upper contact 160) needs to be at least 6nm to ensure enough isolation, and the relative width between the lower contact 132 and the upper contact 160 is unimportant in that their size relative to each other is inconsequential.

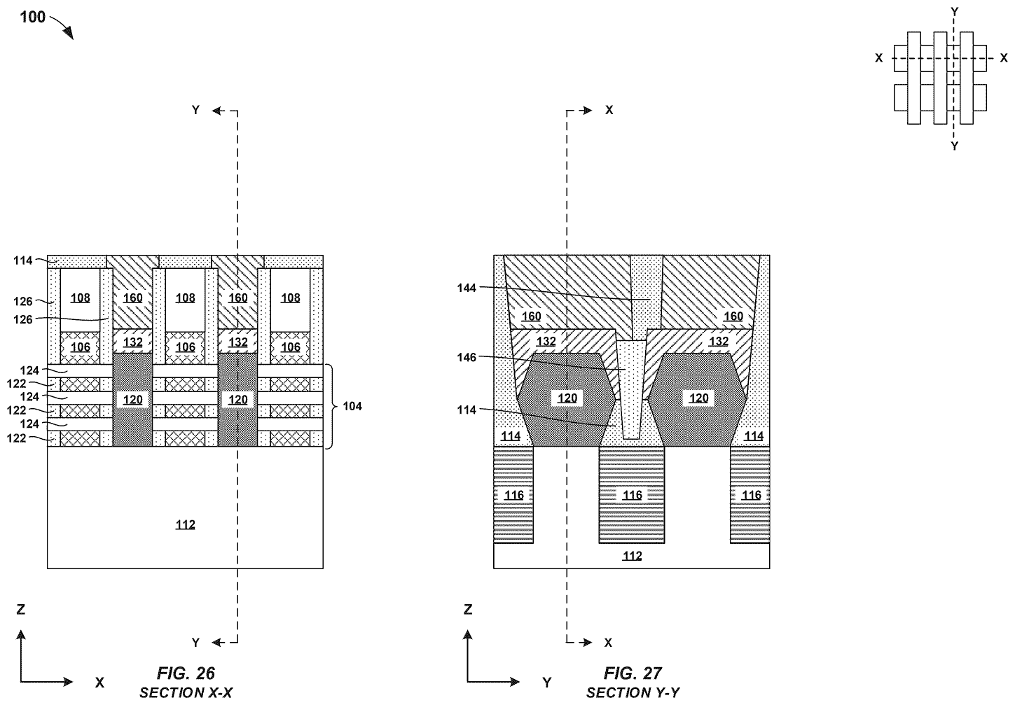

Referring now to FIGS. 26 and 27, the structure 100 is shown after upper contact metallization, according to an embodiment of the invention. FIG. 26 depicts a cross-sectional view of the structure 100 shown in FIG. 27 taken along line XX and FIG. 27 depicts a cross-sectional view of the structure 100 shown in FIG. 26 taken along line YY.

Differentiated from FIGS. 24-25, FIGS. 26-27 show an embodiment in which the lower contact cut 146 is recessed into the lower contact 132. Recessing the lower contact cut 146 allows for a larger contact area for the middle-of-line contact (e.g., between the lower contact 132 and the upper contact 160). As illustrated, the upper contact 160 and the upper contact cut 144 are partially formed on top of the lower contact cut 146 within the recession.

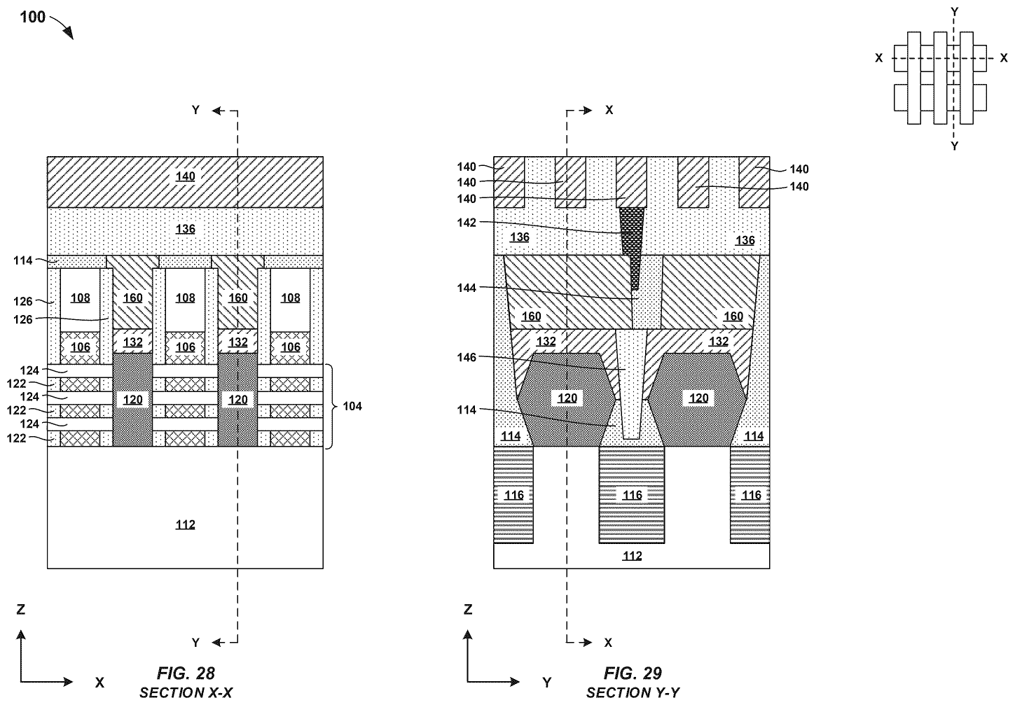

Referring now to FIGS. 28 and 29, the structure 100 is shown after formation of a back-end-of-line (BEOL), ILD, V0, and M1, according to an embodiment of the invention. FIG. 26 depicts a cross-sectional view of the structure 100 shown in FIG. 27 taken along line XX and FIG. 27 depicts a cross-sectional view of the structure 100 shown in FIG. 26 taken along line YY.

The back-end-of-line 136 may include vias and metal lines which may be generally referred to as back-end-of-line interconnects. The vias and the metal lines are formed according to known techniques. In addition, a VA 142, and one or more M1 140 are formed using known techniques.

When forming the VA 142, the back-end-of-line 136 is etched down until the upper contact 160 is exposed. However, if the etching is misaligned, a recess left by the etching process overlaps with the upper contact cut 144, and because the upper contact cut 144 is a similar material as the back-end-of-line 136 (also dielectric), the misaligned etching process results in also removing a portion of the upper contact cut 144. Formation of the VA 142 may then proceed to metallization of the recess (i.e., etched portion of the back-end-of-line 136 as well as any etched portions of the upper contact cut 144), resulting in the VA 142 extending to a depth beyond a surface of the upper contact 160.

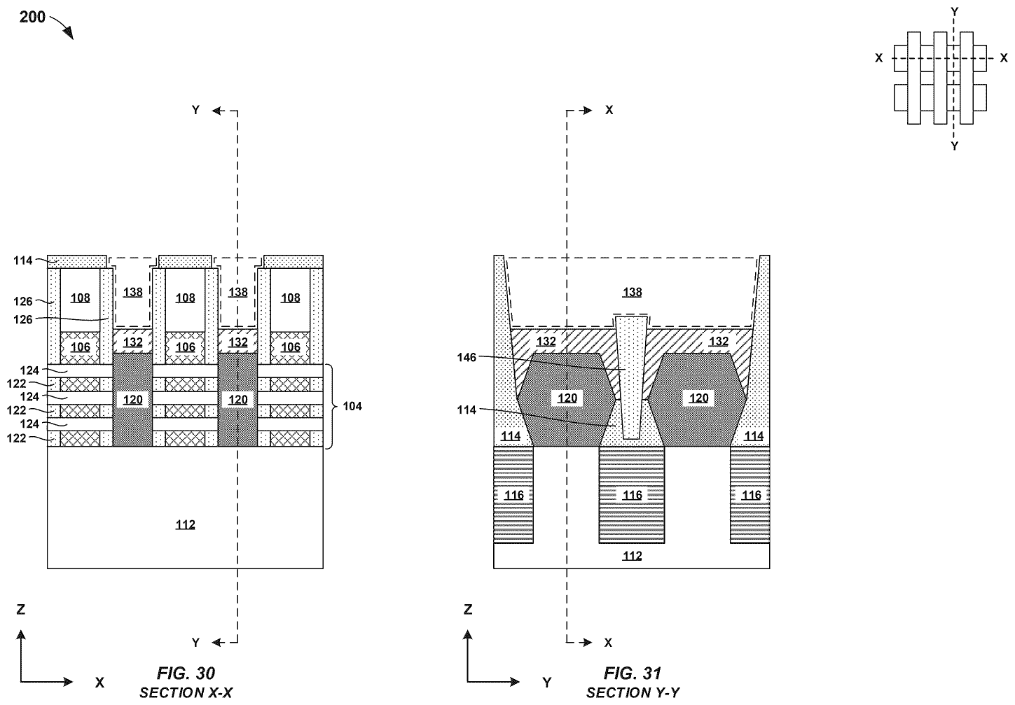

FIGS. 30-35 depict an alternative method for fabrication of a structure 200 having the same advantages as that of the structure 100. Overall, the structure 200 comprises the same components as that of the structure 100, however the positioning of those components varies as described forthcoming.

Referring now to FIGS. 30 and 31, the semiconductor structure 200 is shown after recessing the lower contact, according to an embodiment of the invention. FIG. 30 depicts a cross-sectional view of the structure 100 shown in FIG. 31 taken along line XX and FIG. 31 depicts a cross-sectional view of the structure 100 shown in FIG. 30 taken along line YY.

Here, the lower contact 132 may be recessed in accordance with the detailed description up to and accompanying FIGS. 14-15, thereby exposing an upper portion of the lower contact cut 146 and creating the void 138. Optionally, the lower contact cut 146 may be left prouder relative to the lower contact 132 than that of the structure 100.

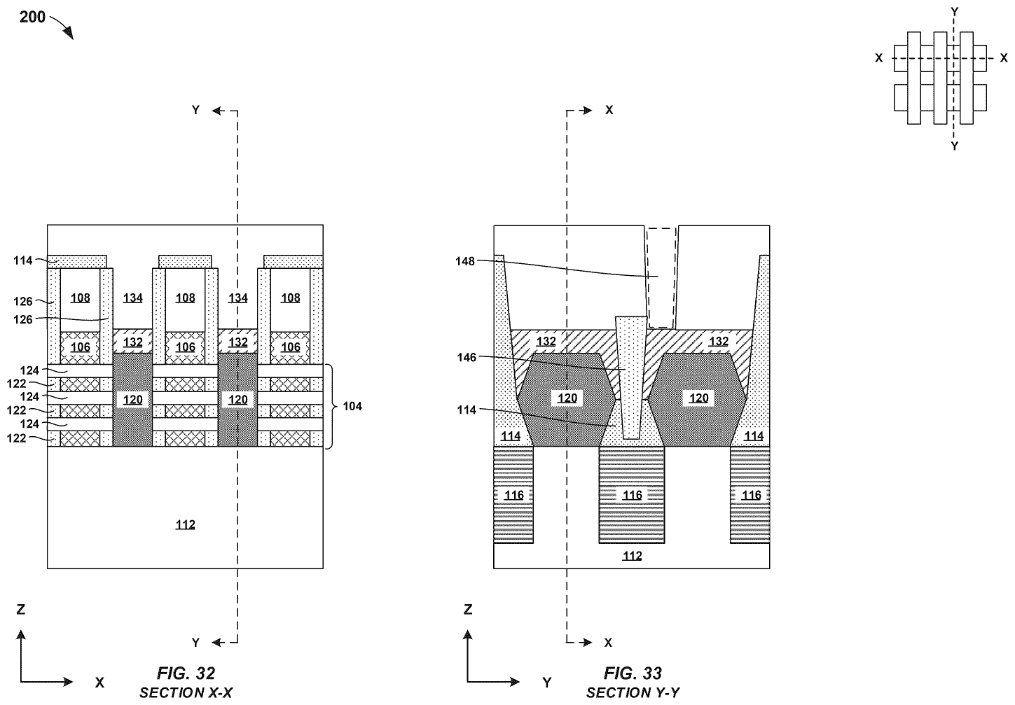

Referring now to FIGS. 32 and 33, the structure 200 is shown after a sacrificial material fill and cut patterning, according to an embodiment of the invention. FIG. 32 depicts a cross-sectional view of the structure 100 shown in FIG. 33 taken along line XX and FIG. 33 depicts a cross-sectional view of the structure 100 shown in FIG. 32 taken along line YY.

The void 138 may be filled with a sacrificial fill material in accordance with the detailed description accompanying FIGS. 16-17. Then, the upper contact cut opening 148 may be patterned. However, unlike the patterning cut of FIGS. 18-19 where the upper contact cut opening 148 is formed above the lower contact cut 146, here, the upper contact cut opening 148 is formed adjacent to and in contact with the lower contact cut 146. The upper contact cut opening 148 may then be filled (shown in subsequent FIGS.) with a dielectric in a similar manner to that described with respect to FIGS. 18-19.

As such, the structure 200 differs mainly from the structure 100 by the positioning of the lower contact cut 146 relative to the upper contact cut 144. More specifically, the embodiments differ by a level of overlap between the lower contact cut 146 and the upper contact cut 144. This methodology is particularly advantageous for addressing the problems caused by 22 of FIG. 3 as it provides greater margin for contact between the VA 142 and M1 140 (see FIG. 35).

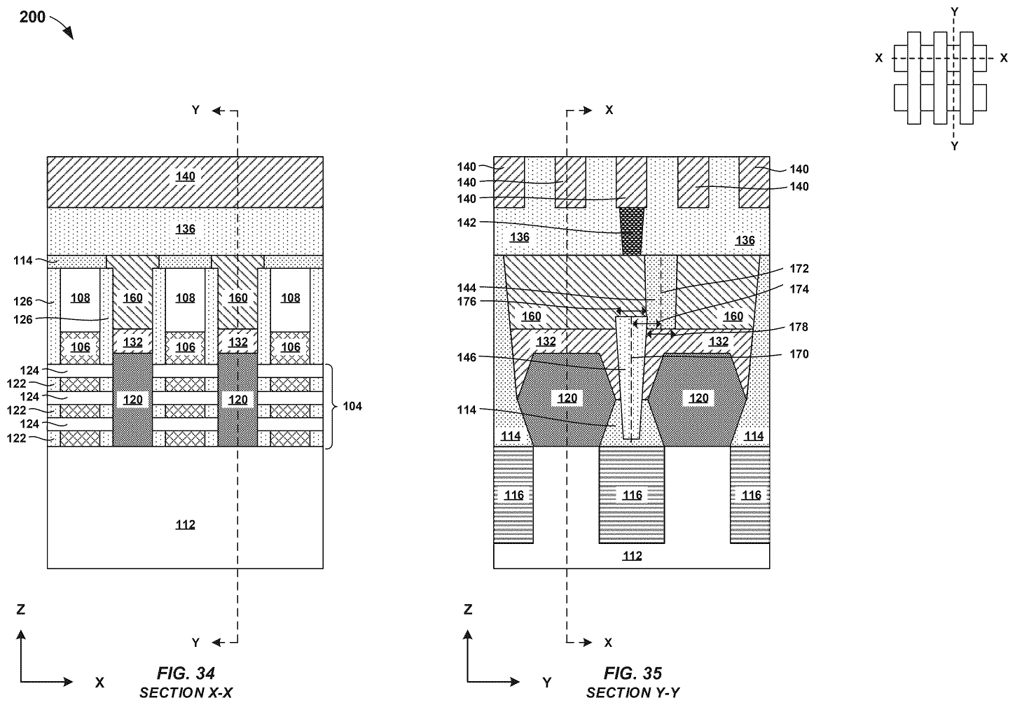

Referring now to FIGS. 34 and 35, the structure 200 is shown after formation of a back-end-of-line (BEOL), ILD, V0, and M1, according to an embodiment of the invention. FIG. 34 depicts a cross-sectional view of the structure 100 shown in FIG. 35 taken along line XX and FIG. 35 depicts a cross-sectional view of the structure 100 shown in FIG. 34 taken along line YY.

The back-end-of-line (BEOL) 136, the VA 142, and one or more M1 140 may be formed in a substantially similar manner to that described with respect to FIGS. 28-29. Here, however, the filled.

As illustrated by FIG. 35, a centerline 172 of the upper cut 144 and a centerline 170 of the lower cut 146 may be parallel and have an offset 174 relative to each other. The offset may be selected (in a positive or negative direction) to accommodate additional contact area between the VA 142 and the upper contact 160. The offset 174 may be advantageous when fabrication of the VA 142 and/or the one or more M1 are misaligned with the upper contact 160. The offset 174 may be selected such that the upper cut 144 and the lower cut 146 remain directly adjacent. Using two, connected cuts (the upper cut 144 and the lower cut 146) in conjunction with the staggering provided by the offset 174, the claimed invention provides an advantage in that the lower cut 146 may remain positioned between the source/drain regions 120 while the upper cut 144 may be positioned to optimize contact between the upper contact 160 and the VA 142. The offset 174 may additionally serve to prevent inadvertent contact between the VA 142 and one of the upper contacts 160. As additionally illustrated by FIG. 35, a width 176 of an upper surface of the lower cut 146 may be wider than a width 178 of a lower surface of the upper cut 144.

With continued reference to FIGS. 34 and 35, and according to an embodiment, the structure 100 includes a first source/drain region of a first transistor and a second source/drain region of a second transistor. According to the embodiment, the semiconductor structure may further include a source/drain contact block having a first source/drain contact in contact with the first source/drain region of the first transistor and a second source/drain contact in contact with the second source/drain region of the second transistor. According to the embodiment, the first source/drain contact and the second source/drain contact of the source/drain contact block are separated by a lower contact cut and an upper contact cut.

With continued reference to FIGS. 34 and 35, and according to an embodiment, a bottom surface of the upper contact cut is smaller than a top surface of the lower contact cut.

With continued reference to FIGS. 34 and 35, and according to an embodiment, the first source/drain contact and the second source/drain contact respectively further comprise a lower portion and an upper portion.

With continued reference to FIGS. 34 and 35, and according to an embodiment, the upper contact cut has a first offset with respect to the lower contact cut.

With continued reference to FIGS. 34 and 35, and according to an embodiment, a width of the first offset is no more than half of a width of a bottom surface of the upper contact cut.

With continued reference to FIGS. 34 and 35, and according to an embodiment, a width of the first offset is substantially close to half of a width of a bottom surface of the upper contact cut.

With continued reference to FIGS. 34 and 35, and according to an embodiment, the structure includes a via, and wherein the via has a second offset from the upper contact cut such that the via makes contact with the upper portion.

With continued reference to FIGS. 34 and 35, and according to an embodiment, a lower surface of the upper contact cut is below a top surface of the lower contact cut.

With continued reference to FIGS. 28 and 29, and according to an embodiment, a lower surface of the upper contact cut is above a top surface of the lower contact cut.

With continued reference to FIGS. 34 and 35, and according to an embodiment, the lower contact cut is at least partially formed within an interlayer dielectric.

With continued reference to FIGS. 34 and 35, and according to an embodiment, at least part of the lower contact cut is formed horizontally between the first source/drain region and the second source/drain region.

With continued reference to FIGS. 34 and 35, and according to an embodiment, the structure includes a via, and wherein the via is in contact with the upper portion and the upper contact cut.

With continued reference to FIGS. 34 and 35, and according to an embodiment, the first source/drain contact partially wraps around sidewalls of the first source/drain region near adjacent to the lower contact cut.

With continued reference to FIGS. 34 and 35, and according to an embodiment, the structure includes two or more source/drain regions and two cuts that are parallel, horizontally offset, vertically staggered, and filled with dielectric material formed horizontally between the two or more source/drain regions.

With continued reference to FIGS. 34 and 35, and according to an embodiment, the structure includes a source/drain contact in contact with the two or more source/drain regions; and wherein the two cuts are further formed within the source/drain contact.

With continued reference to FIGS. 34 and 35, and according to an embodiment, the structure includes a via, and wherein the via is offset from at least one of the two cuts and in contact with the source/drain contact.

With continued reference to FIGS. 34 and 35, and according to an embodiment, the structure includes an interlayer dielectric, and wherein the two cuts are at least partially formed within the interlayer dielectric.

With continued reference to FIGS. 34 and 35, and according to an embodiment, the structure includes a source/drain contact and two or more cuts vertically bifurcating the source/drain contact.

With continued reference to FIGS. 34 and 35, and according to an embodiment, the structure includes two or more source/drain regions in contact with the source/drain contact, and wherein the two or more cuts further bifurcate the two or more source/drain regions.

With continued reference to FIGS. 34 and 35, and according to an embodiment, the two or more cuts are in contact but vertically stacked and horizontally offset.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a first source/drain region of a first transistor and a second source/drain region of a second transistor; and
a source/drain contact block having a first source/drain contact in contact with the first source/drain region of the first transistor and a second source/drain contact in contact with the second source/drain region of the second transistor,
wherein the first source/drain contact and the second source/drain contact of the source/drain contact block are separated by a lower contact cut and an upper contact cut.

2. The semiconductor structure of claim 1, wherein a bottom surface of the upper contact cut is smaller than a top surface of the lower contact cut.

3. The semiconductor structure of claim 1, wherein the first source/drain contact and the second source/drain contact respectively further comprise a lower portion and an upper portion.

4. The semiconductor structure of claim 3, wherein the upper contact cut has a first offset with respect to the lower contact cut.

5. The semiconductor structure of claim 4, wherein a width of the first offset is no more than half of a width of a bottom surface of the upper contact cut.

6. The semiconductor structure of claim 4, wherein a width of the first offset is substantially close to half of a width of a bottom surface of the upper contact cut.

7. The semiconductor structure of claim 4, further comprising a via, and wherein the via has a second offset from the upper contact cut such that the via makes contact with the upper portion.

8. The semiconductor structure of claim 1, wherein a lower surface of the upper contact cut is below a top surface of the lower contact cut.

9. The semiconductor structure of claim 1, wherein a lower surface of the upper contact cut is above a top surface of the lower contact cut.

10. The semiconductor structure of claim 1, wherein the lower contact cut is at least partially formed within an interlayer dielectric.

11. The semiconductor structure of claim 1, wherein at least part of the lower contact cut is formed horizontally between the first source/drain region and the second source/drain region.

12. The semiconductor structure of claim 1, further comprising a via, and wherein the via is in contact with the upper portion and the upper contact cut.

13. The semiconductor structure of claim 1, wherein the first source/drain contact partially wraps around sidewalls of the first source/drain region near adjacent to the lower contact cut.

14. A semiconductor structure comprising:
two or more source/drain regions; and
two cuts that are parallel, horizontally offset, vertically staggered, and filled with dielectric material formed horizontally between the two or more source/drain regions.

15. The semiconductor structure of claim 14, further comprising:
a source/drain contact in contact with the two or more source/drain regions; and wherein the two cuts are further formed within the source/drain contact.

16. The semiconductor structure of claim 15, further comprising:
a via, and wherein the via is offset from at least one of the two cuts and in contact with the source/drain contact.

17. The semiconductor structure of claim 14, further comprising:
an interlayer dielectric, and wherein the two cuts are at least partially formed within the interlayer dielectric.

18. A semiconductor structure comprising:
a source/drain contact; and
two or more cuts vertically bifurcating the source/drain contact.

19. The semiconductor structure of claim 18, further comprising:
two or more source/drain regions in contact with the source/drain contact; and
wherein the two or more cuts further bifurcate the two or more source/drain regions.

20. The semiconductor of claim 18, wherein the two or more cuts are in contact but vertically stacked and horizontally offset.
